(19) United States
(12) Patent Application Publication
(10) Pub. No.: US 2008/0265257 A1
(43) Pub. Date: Oct. 30, 2008

(54) THIN FILM TRANSISTOR

(76) Inventors: Peter James Fricke, Corvallis, OR (US); Ronald A. Hellekson, Eugene, OR (US); Alan R. Arthur, Salem, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/740,568

(22) Filed: Apr. 26, 2007

(51) Int. Cl. H01L 29/04; G06F 3/038

(52) U.S. Cl. 257/72; 345/212; 257/E29.003

(57) ABSTRACT

Embodiments of a thin film transistor (TFT) are disclosed.

### BACKGROUND OF THE INVENTION

Substrates provide a substantially flat surface on which to grow or form active devices for decoding arrays of electrically activated elements used to display information and media. Substrates often provide mechanical strength to such displays but can also be flexible. Substrates are usually electrically non-conductive and may vary in thickness depending on the mechanical strength needed and the cost targeted in manufacturing. Processes build active devices by forming layers of semiconductor materials and conductive interconnects on top of each other on the substrate. Usually at least two conductive layers and a via interconnect on a substrate have been needed for building and interconnecting transistor logic devices to implement cross-overs between the semiconductor source/drain interconnect and the gate interconnect. However, optimizing substrate area usually requires adding additional layers and vias above the two layers needed for active devices. Additional layers and vias add considerably to the cost of processing an end product and are therefore less desirable in low-cost products.

### BRIEF DESCRIPTION OF THE DRAWINGS

FIG. 1 is a cross-sectional view of a thin film transistor in accordance with an embodiment;

FIG. 2 is a cross-sectional view of a thin film transistor further comprising a dielectric layer formed between the gate and substrate in accordance with an embodiment;

FIG. 3 is a schematic representation of a thin film transistor in accordance with an embodiment;

FIG. 4 is a schematic representation of a select driver portion of a thin film decoder in accordance with an embodiment;

FIG. 5 is a top view of a mask representation of a select driver portion of the thin film decoder in accordance with an embodiment;

FIG. 6 is a schematic representation of the active pull-down portion of an thin film decoder in accordance with an embodiment;

FIG. 7 is a top view of a mask representation of an active pull-down portion of the active thin film decoder in accordance with an embodiment;

FIG. 8 is a block diagram and schematic representation of the thin film decoder and a small pixel element array in accordance with an embodiment; and

FIG. 9 is a flow chart of an embodiment using the double-sided thin film transistor decoder to address rows of a bistable array.

### DETAILED DESCRIPTION

Reference will now be made to the exemplary embodiments illustrated in the drawings, and specific language will be used herein to describe the same. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

An embodiment of a thin film transistor (TFT) configured to be used in a bi-stable display, has a substrate with a first side and second side configured to be used with the bi-stable material in the bi-stable display. A source and a drain are formed on the first side of the substrate in contact with a semiconductor material between a source connection and the drain connection. A gate is formed on a second side of the substrate opposite the semiconductor material.

A double-sided thin film transistor reduces conductor cross-over by allowing gate routing on a substrate side to be completely independent of the source-drain routing on the other side. The conductor materials may include nickel, aluminum, and indium-tin-oxide (ITO) and the like. A double-sided transistor implementation of the decoder pass transistor logic enables a cost reduction by using a single layer interconnect and also allows an area reduction in interconnect. Therefore, the active thin film transistor decoder implemented in double sided pass gates provides a high performance, low cost advantage for addressing bi-stable displays.

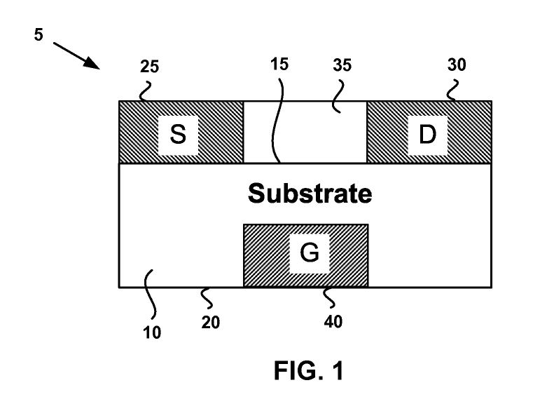

FIG. 1 is a cross-sectional view of a thin film transistor 5 in accordance with an embodiment configured to be used in a bi-stable display. A substrate 10 has a first side 15 and second side 20. A source 25 and a drain 30 are formed on the first side of the substrate in contact with a semiconductor material 35. The semiconductor materials may include silicon (amorphous and poly), zinc indium oxide, zinc tin oxide, other zinc oxides, and the like.

A gate 40 is formed for a second side 20 of the substrate 10 opposite the semiconductor material 35. Gates that are self-aligned to source drain geometries in an embodiment contribute to greater gain for the thin film transistor. The substrate 10 provides an insulator between the gate 40 and the semiconductor material 35. The substrate materials may include polyimide (e.g. kapton), polyetheretherketone (PEEK), polyethersulfone (PES), polyetherimide (PEI), polyethylenenaphthalate (PEN) and the like.

The gate insulator thickness can be controlled by an embossing process or a laser ablation process or both in a further embodiment. In the depicted embodiment, the gate is recessed into an area that has been ablated by a laser or some other substrate removal process. However, the gate may be formed on the second side of the substrate without removing any of the substrate.

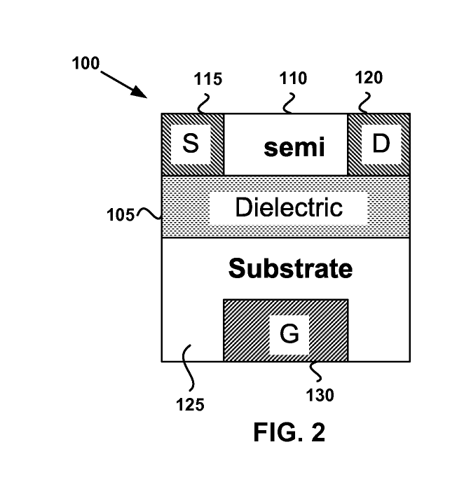

FIG. 2 is a cross-sectional view of a thin film transistor 100 further comprising a dielectric layer 105 formed between the semiconductor 110 the source 115 and drain 120 areas and the substrate 125 in accordance with an embodiment. The substrate 125 with the dielectric 105 as insulators may further provide higher gate capacitance values and correspondingly better transistor performance. The dielectric may include a composite of materials having different dielectric coefficients to further increase gate capacitance and the thin film transistor performance. Dielectric materials may include silicon nitride (SiN), aluminum oxide, hafnium oxides, zirconium oxides, and the like.

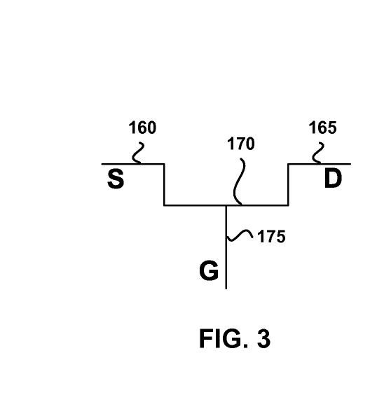

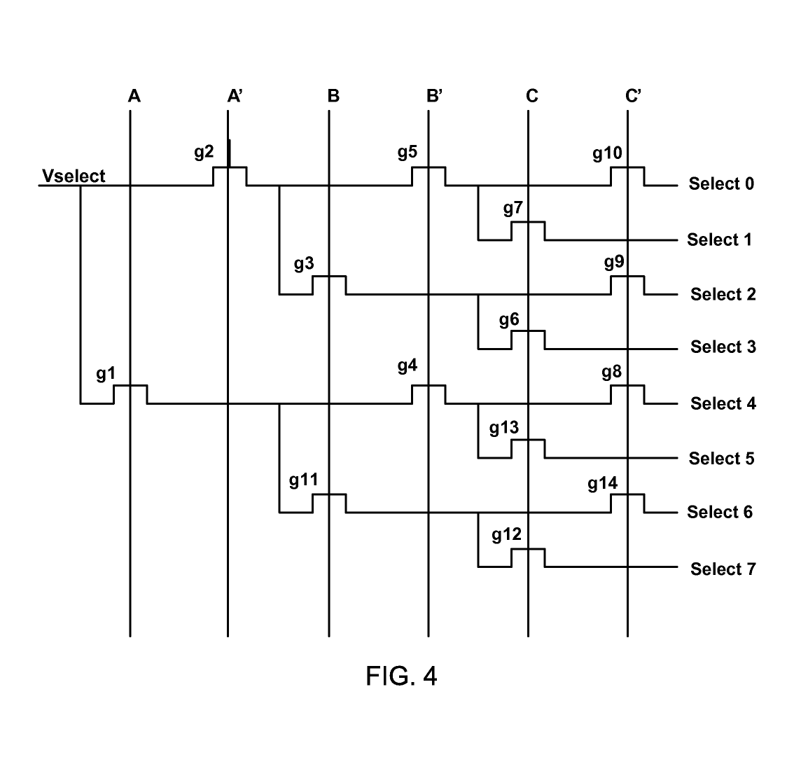

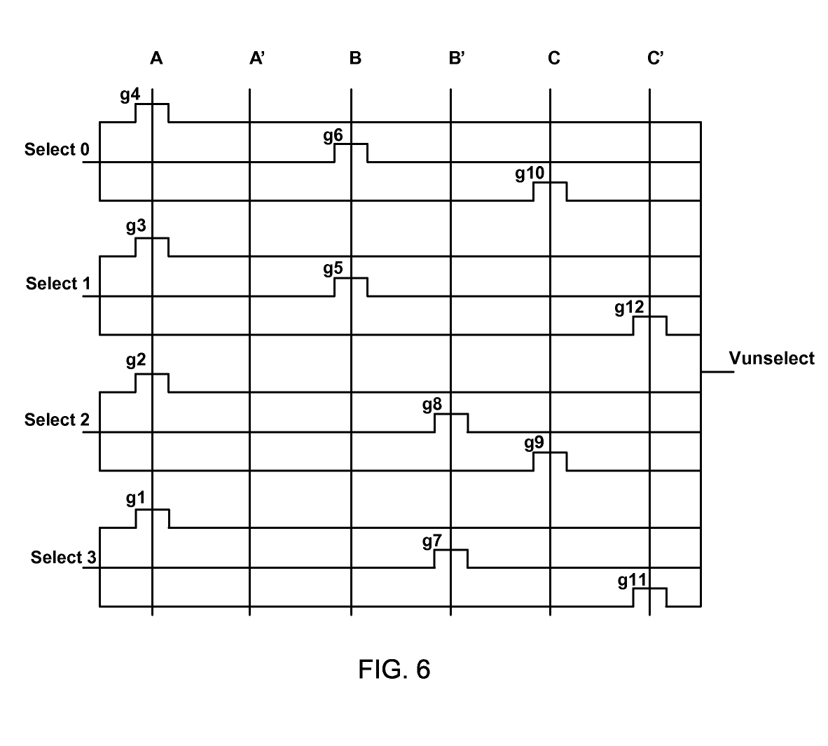

FIG. 3 is a schematic representation of a thin film transistor in accordance with an embodiment. The source connection 160 is electrically connected to the drain connection 165 through a semiconductor 170 which is controlled by the gate connection 175. This schematic representation is used in FIGS. 4 and 6.

FIG. 4 is a schematic representation of the select driver portion of a thin film double-sided decoder in accordance with an embodiment. Control signals A′, B′, and C′ are logically complementary of respective signals A, B, and C. Driver source Vselect is electrically interconnected to one of the select outputs Select 0 through Select 7 depending on the decoding of the control signals A, B, C, and A′, B′, and C′ through the fourteen double sided thin film transistors depicted. Therefore an electrically conductive path for the driver source Vselect to Select 0 is formed through double sided thin film transistors g2, g5, and g10 and interconnect when control signals A′, B′, and C′ are active. Likewise, Vselect is electrically connected to Select 7 when the thin film transistors g1, g11, and g12 are activated by control signals A, B, and C.

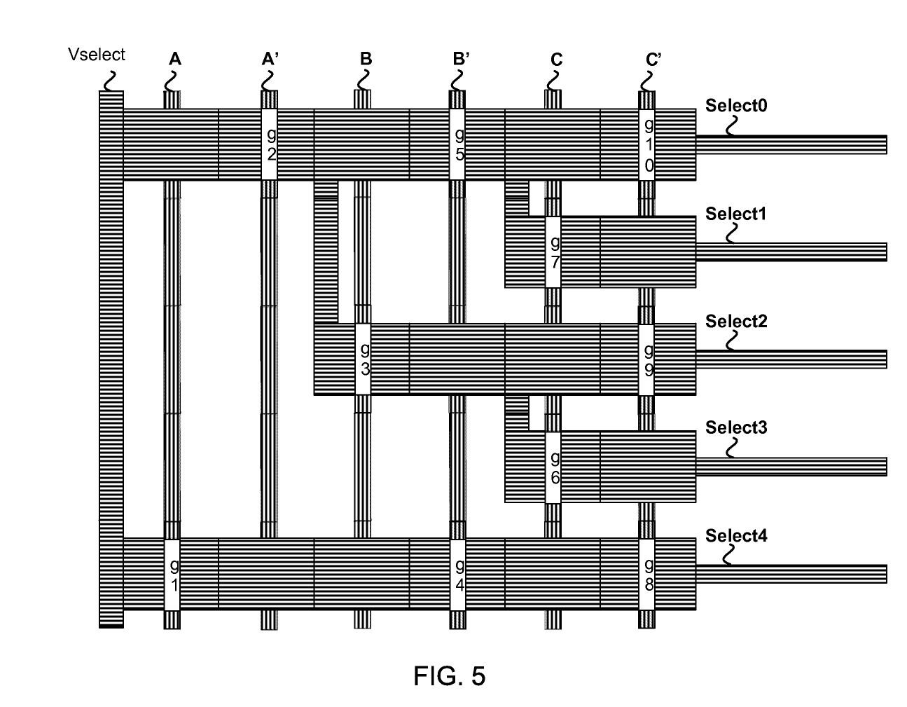

FIG. 5 is a top view of a mask representation of a select driver portion of the thin film double-sided decoder in accordance with an embodiment configured to be used in a bi-stable display. It includes gates g1 through g10 formed on a second side of the substrate with interconnections formed entirely on the second side. Semiconductor areas or geometries formed on the first side oppose a gate. A first area adjacent the semiconductor forms a source connection and a second adjacent area forms a drain connection on the first side with interconnections formed entirely on the first side. Driver source Vselect is electrically interconnected to one of the select outputs Select 0 through Select 4 depending on the decoding of the control signals A, B, C, and A′, B′, and C′ through the ten double-sided thin film transistors depicted. Therefore an electrically conductive path for the driver source Vselect to Select 0 occurs through double sided thin film transistors g2, g5, and g10 and through side 1 interconnection. Select 0 line may provide a voltage on a row of pixel elements in a pixel array. Likewise, Vselect is electrically connected to Select 4 when the thin film transistors g1, g4, and g8 are activated by control signals A, B′, and C′.

FIG. 6 is a schematic representation of the active pull-down portion of a thin film double-sided decoder in accordance with an embodiment. Control signals A′, B′, and C′ are logically complementary of respective signals A, B, and C. Driver source Vunselect is electrically interconnected to one of the Select outputs Select 0 through Select 3 depending on the decoding of the control signals A, B, C, and A′, B′, and C′ through the twelve double-sided thin film transistors depicted. There are no pull-down transistors on control signals A′, B′, and C′ so that Vunselect is mutually exclusive with Vselect on the Select 0 output of the select driver side of the decoder. Rather when the control signals A, B, and C are active, an electrically conductive path is provided by either of the transistors g4, g6, and g10 from Vunselect to Select 0.

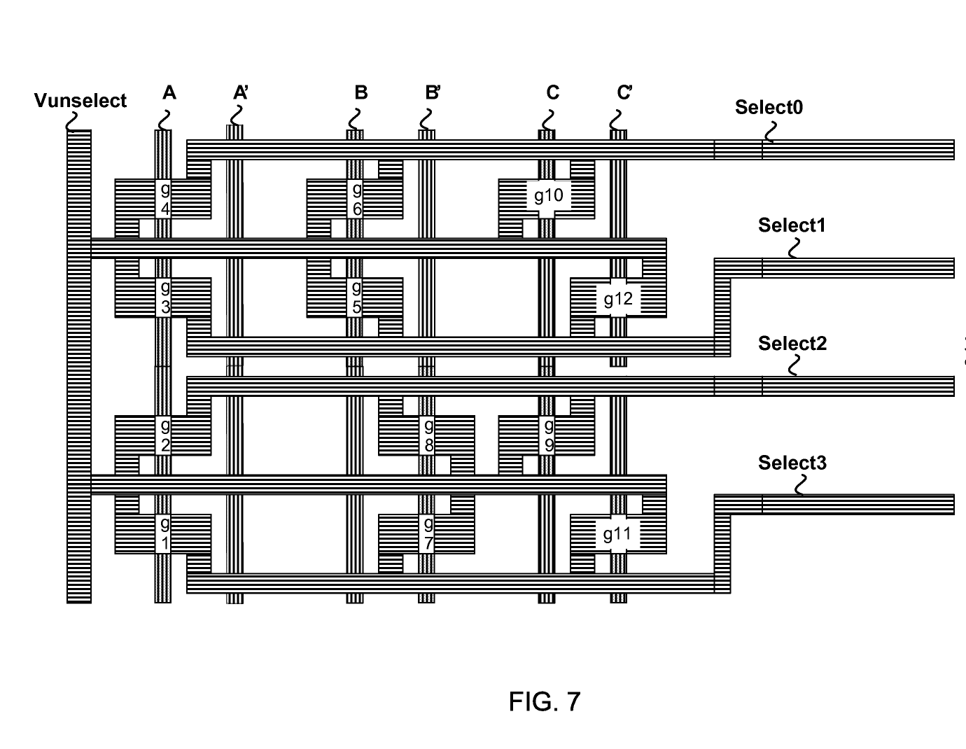

FIG. 7 is a top view of a mask representation of an active pull-down portion of the thin film double-sided decoder in accordance with an embodiment configured to be used in a bi-stable display. It includes gates g1 through g12 formed on a second side of the substrate with interconnections formed entirely on the second side. Semiconductor areas are formed on the first side opposing a gate. A first area adjacent the semiconductor forms a source connection and a second adjacent area forms a drain connection on the first side with interconnections formed entirely on the first side. Driver source Vunselect is electrically interconnected to one of the Select outputs Select 0 through Select 3 depending on the decoding of the control signals A, B, C, and A′, B′, and C′ through the twelve double sided thin film transistors depicted. Therefore an electrically conductive path for the driver source Vunselect to Select 0 occurs through double sided thin film transistors g4, g6, and g10 and through side 1 interconnection.

Decoders allow activation of single electrically activated elements. Decoding an array is usually accomplished by breaking up the array into column and row addresses and generating true and complement signals for each row and each column address. Therefore decoders may also have the ability to electrically activate entire rows or entire columns in an array at any given instant or simultaneously through multiple decoders. Decoders typically take up a significant amount of area contiguous to an array of electrically activated elements. It is therefore desirable to optimize the area consumed by decoding row and column addresses as well as to minimizing the number of inputs into a decoder. In addition to minimizing the area in a decoder there is also a desire to minimize the number of layers or masks needed to build the decoder. Two conductive layers has generally been the limit on how cheaply a decoder could be implemented because at least two layers and a via interconnect have been needed to implement cross-overs between rows and columns in the array itself. Also where a decoder and an array are built in the same process it is more cost effective to match the number of layers in the decoder with the number of layers in the array.

In a decoder embodiment, a semiconductor formed on the first side is aligned to an opposing gate on the second side. Source and drain interconnections formed on the first side are formed entirely in one conductive layer. Also the gate control lines formed on the second side are formed entirely in one conductive layer. Pass transistors are implemented with double sided transistors where a gate on the second side and a semiconductor on the first side allow source and drain connections entirely on the first side of the substrate insulator. Furthermore, in an embodiment, the decoder is implemented in pass transistors of one type fabricated in materials and processes of one type.

An embodiment of the decoder further comprises a first set of pass transistors connected to a first input and a second set of pass transistors connected to a second input, wherein the second input is channeled to an output mutually exclusive of the first input. Furthermore, control signals for the first and second set of pass transistors are logical complements of each other. Implementing the active thin film transistor decoder in pass transistors allows the gate to source voltage difference to be used as way to control voltage levels seen at the output of the decoder into the pixel electrode array.

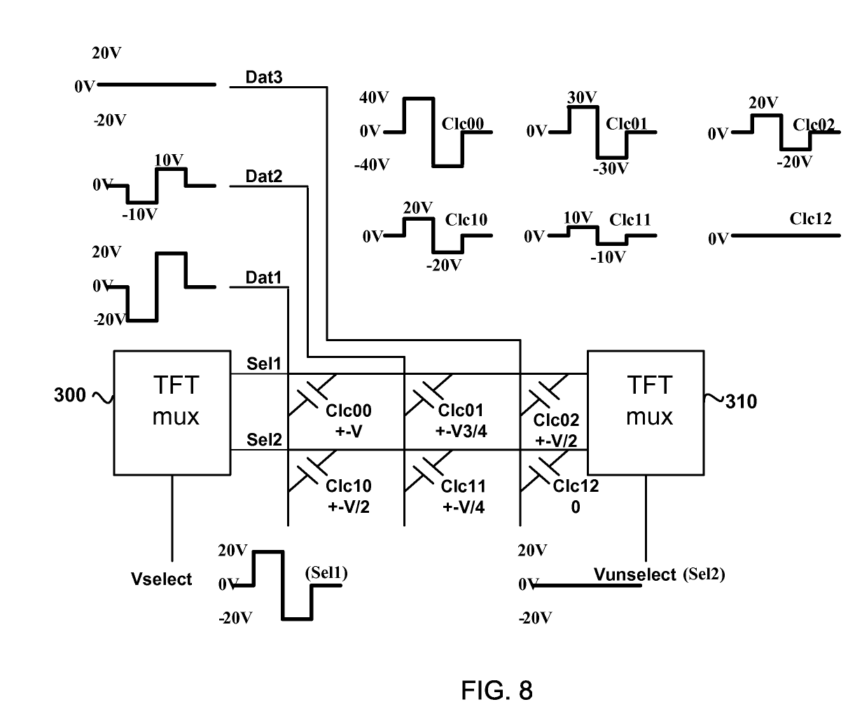

FIG. 8 is a block diagram representation of the thin film double-sided decoder and an example pixel element array in accordance with an embodiment. The select driver portion 300 decodes the voltage source Vselect onto Sel1 and Sel2. The active pull-down portion 310 decodes the voltage sink Vunselect onto Sel1 and Sel2 mutually exclusively with the source Vselect. In this depicted embodiment, Vselect is a voltage supply with alternating positive and negative polarities. A plurality of other voltage supplies for data lines Dat1, Dat2, and Dat3 of alternating positive and negative polarities are applied onto a first electrode of pixel elements in an array. The voltage polarity cycles of Vselect and Dat1, Dat2, and Dat3 are in phase.

The voltage difference applied across pixel element Clc00 is a plus or minus 40 volts as a result of an alternating +20 volts and −20 volts applied through Sel1 and an alternating +20 volts and −20 volts applied on Dat1. The voltage difference applied across pixel element Clc10 is a plus or minus 20 volts as a result of an alternating +20 volts and −20 volts applied through Dat1 and 0 volts applied on Sel2. Accordingly the voltage difference across Clc01 is a plus or minus 30 volts, and the voltage difference across Clc11 is a plus or minus 10 volts. Dat3 is at 0 volts and Sel2 is also at 0 volts so the voltage difference across Clc12 is 0 volts. The voltage across Clc02 is similar to that across Clc10.

A data line Dat1, Dat2, or Dat3 on the second side of the substrate may provide a voltage on a column of pixel elements in a pixel array. A select line Sel1 or Sel2 on the first side of the substrate may provide a voltage on a row of pixel elements in a pixel array. The voltage difference across a pixel element between a select line Sel1 or Sel2 and a data line Dat1, Dat2, or Dat3 may activate a pixel element when it is above the pixel element threshold.

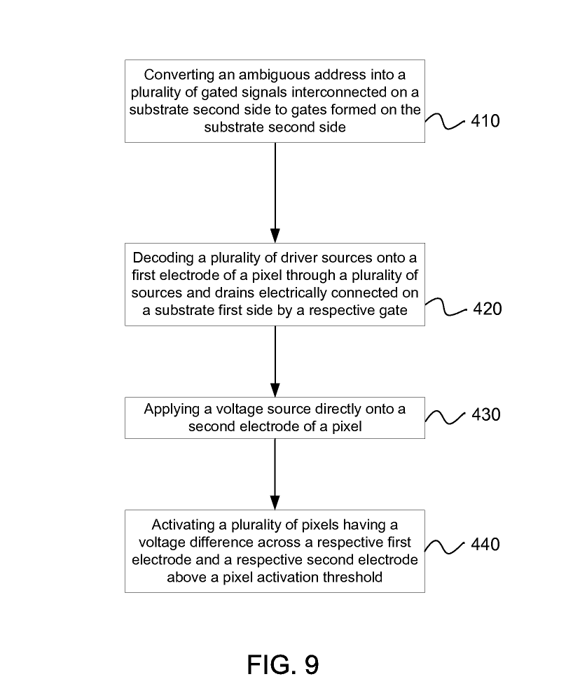

FIG. 9 is a flow chart of an embodiment for passively addressing a bistable array using the double-sided thin film transistor decoder. The embodied method includes the step of converting an ambiguous address into a plurality of gated signals interconnected on a substrate second side to gates formed on the substrate second side as in block 410. Additionally, the step of decoding a plurality of driver sources onto a first electrode of a pixel element, through a plurality of sources and drains electrically connected on a substrate first side by a respective gate as in block 420 is included. A voltage source is applied directly onto a second electrode as in block 430. Pixel elements are activated having a voltage difference across a respective first electrode and a respective second electrode above a pixel element activation threshold, as in block 440.

Decoding ambiguous addresses allows time multiplexing of multiple voltage sources to rows or columns of pixel electrodes. In other words, the voltage source is presented to an electrode as a transistor driver source that is switched through the decoder circuitry. Vselect may be present on a particular electrode at one point in time through the decoder and at another point in time Vunselect may be presented on that same electrode through the decoder. Ambiguous addressing allows addressing larger arrays of electronically controlled elements than would be possible with unambiguous addressing. Thus, the voltage difference across a pixel element needed to activate that element can be controlled by multiple sources. The thin film transistor double-sided decoder allows an ambiguous address to be presented on one side of a substrate while the voltages needed to unambiguously activate a row or column in an array are presented on the other side of the substrate.

In an alternative embodiment, a method can use multiple thin film double-sided transistor decoders. The embodied method includes the step of decoding a plurality of voltage supplies of alternating positive and negative polarities onto a first electrode of a pixel element. Additionally, decoding a voltage supply with alternating positive and negative polarities onto the second electrode of the pixel element rather than directly applying a voltage supply to the second electrode is further included. Synchronizing voltage polarity cycles of the decoded voltage and the applied voltages, applies a pre-determined voltage difference across a first electrode to a second electrode. Pixel elements are activated having an applied voltage above the pixel element activation threshold. The multiple voltage supplies may include static sources of various voltage levels including a source having a mean voltage of the alternating positive and negative polarities.

It is to be understood that the above-referenced arrangements are only illustrative of the application for the principles of the present invention. Numerous modifications and alternative arrangements can be devised without departing from the spirit and scope of the present invention. While the present invention has been shown in the drawings and fully described above with particularity and detail in connection with what is presently deemed to be the most practical and preferred embodiment(s) of the invention, it will be apparent to those of ordinary skill in the art that numerous modifications can be made without departing from the principles and concepts of the invention as set forth herein.

1. A thin film transistor (TFT) configured to be used in a bi-stable display, comprising:
a substrate having a first side and second side configured to be used with the bi-stable material in the bi-stable display;
a source formed on the first side of the substrate;
a drain formed on the first side of the substrate;
a semiconductor material on the first side of the substrate between the source connection and the drain connection; and
a gate formed on a second side of the substrate opposite the semiconductor material.

2. A thin film transistor of claim 1, wherein the substrate is an insulator.

3. A thin film transistor of claim 1, wherein the substrate provides the insulator between the gate and the semiconductor material, the source connection and the drain connection.

4. A thin film transistor of claim 1, further comprising a dielectric layer formed between the semiconductor and substrate.

5. A thin film transistor of claim 1, further comprising the source and drain formations on the first side being self-aligned with the gate formations on the second side.

6. A thin film transistor of claim 1, wherein the gate insulator thickness is controlled by an embossing process.

7. A thin film transistor of claim 1, wherein the gate insulator thickness is controlled by a laser ablation process.

8. A thin film transistor (TFT) decoder configured to be used in a bi-stable display, comprising:
a substrate having a first side and second side configured to be used with the bi-stable material in the bi-stable display;
a plurality of gates formed on the second side having interconnections formed on the second side;
a plurality of semiconductor areas formed on the first side opposite a respective gate and an adjacent source area and drain area on the first side having interconnections formed on the first side; and
a plurality of driver sources on the first side interconnected to a plurality of outputs on the first side through the plurality of semiconductor areas.

9. The decoder of claim 8, wherein a semiconductor formed on the first side is aligned to an opposing gate on the second side.

10. The film transistor (TFT) decoder of claim 8, wherein the sources and drains formed on the first side are formed entirely in one conductive layer.

11. The film transistor (TFT) decoder of claim 8, wherein the gate control lines formed on the second side are formed entirely in one conductive layer.

12. The film transistor (TFT) decoder of claim 8, wherein a gate on the second side and a semiconductor area on the first side having a source and a drain on the first side form a pass transistor.

13. The film transistor (TFT) decoder of claim 12, further comprising a first plurality of pass transistors connected to a first input and a second plurality of pass transistors connected to a second input, wherein the second input is channeled to an output mutually exclusive of the first input.

14. The film transistor (TFT) decoder of claim 13, further comprising a first plurality of control signals for the first plurality of pass transistors and a second plurality of control signals for the second plurality of pass transistors wherein the second plurality of control signals and the first plurality of control signals are logical complements of each other.

15. The film transistor (TFT) decoder of claim 11, wherein the first plurality of pass transistors are fabricated in a first type of semiconductor material using a first set of processing steps and the second plurality of pass transistors are also fabricated in the first type of semiconductor material using the first set of processing steps.

16. A method of passively addressing pixel elements in a bistable array using a substrate having a substrate first side and substrate second side, comprising:
converting the address into a plurality of gated signals interconnected on a substrate second side to a plurality of gates formed on the substrate second side;
decoding a plurality of driver sources onto a first electrode of a pixel element through a plurality of sources and drains electrically connected on a substrate first side by a respective gate;
applying a voltage source directly onto a second electrode of a pixel element;
activating a plurality of pixel elements having a voltage difference across a respective first electrode and the second electrode above a pixel element activation threshold.

17. The method of claim 16, wherein the step of applying a voltage source to the second electrode of the pixel element further comprises a voltage source having alternating positive and negative polarities.

18. The method of claim 16, wherein the step of applying a voltage source to the second electrode of the pixel element further comprises a voltage source having a mean voltage of the alternating positive and negative polarities.

19. The method of claim 16 wherein the step of decoding a plurality of driver sources onto the first electrode of a pixel element further comprises a voltage source having alternating positive and negative polarities.

20. The method of claim 16 wherein the step of decoding a plurality of driver sources onto the first electrode of the pixel element further comprises a voltage source having a mean voltage of the alternating positive and negative polarities.
